(19) United States
(12) Patent Application Publication
(10) Pub. No.: US 2003/0128043 A1
(43) Pub. Date: Jul. 10, 2003

(54) Flow thru reaction chamber for sensor chips

(76) Inventors: Patric Zeltz, Kirchzarten (DE); Dieter Pfeifer, Mahlberg (DE); Martin Muller, Dietingen (DE)

Correspondence Address: GRIFFIN & SZIPL, PC, SUITE PH-1, 2300 NINTH STREET, SOUTH, ARLINGTON, VA, 22204, US

(21) Appl. No.: 10/273,335

(22) Filed: Oct. 18, 2002

(30) Foreign Application Priority Data
Oct. 19, 2001 (DE) 101 52 690.3

(51) Int. Cl. G01R 31/02

(52) U.S. Cl. 324/755

(57) ABSTRACT

A device with one or more flow through reaction chambers for investigation of one or more probes on a sensor chip. The device has (a) a sensor chip (b) a number of probe arrays corresponding to a number of samples to be investigated, arranged on the sensor chip spatially separated from one another, (c) an upper portion (d) a number of spatially separated chambers disposed in the upper portion corresponding in number to the number of probe arrays. The chambers are each provided with an inlet opening and an outlet opening. The position and dimension of the probe arrays and the chambers is relatively determined so that, after a sandwich-like combination of the sensor chip with the upper portion a respective precise fit reaction chamber is formed over each probe array with an inlet opening and an outlet opening.

### RELATED PATENT APPLICATIONS

The present application claims priority on German Patent Application No. 10152690.3, filed Oct. 19, 2001, the entire disclosure of which is incorporated herein by reference.

### FIELD OF THE INVENTION

The present invention relates to a device with one or more flow-through reaction chambers for the investigation of one or more samples in a sensor chip.

At present, sample components to be examined are bound to corresponding probes on a sensor chip (for example, for hybridisation, nucleic acid sequences as probes are bound to their complementary detectable sequences), wherein so-called “seal-frames” are glued to the sensor chips and after application of the sample, are sealed with a cover glass to form a reaction chamber. Sensor chips are also known (for example those based on glass sample carriers), on which a reaction chamber is formed by covering with a cover glass with the assistance of a hydrophobic layer (for example, by the silation).

Pastinen et al. (Genom Research, 10(7), 2000, page 1031 ff.) disclose a glass sample carrier with 80 primer-microarrays over which 80 separate miniaturized reaction chambers are formed from conically-shaped silicon rubber, each of the reaction chambers possessing on its upper end an intake opening for introduction of reaction solution.

Various of the known reaction chambers for sensor chips are, however, not suited for flow-through use, that is for continuous filling and emptying, or, as the case may be, for washing. Known flow-through cells, on the other hand, are closed systems in which no probe array can be pressed.

It is therefore an object of the present invention to provide a flow-through reaction chamber for sensor chips which is easy to produce and reusable, and is otherwise easily combinable to a device with a plurality of like flow-through reaction chambers so that a plurality of samples can be simultaneously investigated in one sensor chip.

### SUMMARY OF THE INVENTION

In accordance with the above objects, there is provided a device with one or more flow through reaction chambers for investigation of one or more samples on a sensor chip. The device comprises: (a) a sensor chip; (b) a number of probe arrays corresponding to a number of samples to be investigated, arranged on the sensor chip spatially separated from one another; (c) an upper portion; and (d) a number of spatially separated chambers disposed in the upper portion corresponding in number to the number of probe arrays, the chambers being each provided with an inlet opening and an outlet opening, wherein the position and dimension of the probe arrays and the chambers is relatively determined so that, after a sandwich-like combination of the sensor chip with the upper portion a respective precise fit reaction chamber is formed over each probe array with an inlet opening and an outlet opening.

In a further, preferred embodiment, the device further comprises a chip holder dimensioned to securely hold the chip, wherein the upper portion comprises a silicon rubber mat in which said chambers with inlet openings and outlet openings are formed, and a press plate disposed above the silicon mat, and a pusher disposed above the press plate.

In a still further, preferred embodiment, the chip holder comprises a pusher groove dimensioned to movably receive the pusher, wherein the pusher comprises a plurality of pusher noses, and wherein the chip holder further comprises a plurality of pusher clearances corresponding in number to the number of pusher noses, wherein the pusher is insertable into the pusher grooves by inserting the pusher noses into the pusher clearances so that the pusher is slidable in the pusher groove, and wherein, when the pusher is slid so that the pusher noses are displaced from the pusher clearances, the chip holder, chip, silicon mat, and press plate are securely held together and the precise fit reaction chambers are formed.

In a yet further embodiment, a sealing strip dimensioned to seal the outlet openings or the inlet openings, or both, is also provided.

The above objects are further solved according to the present invention by a device with one or more flow-through chambers for investigation of one or more samples on a sensor chip, comprising:

(a) a sensor chip with spatially-separated probe arrays corresponding in number to the number of samples; and

(b) a number of spatially-separated chambers in an upper region corresponding in number to the number of probe arrays, wherein the position and dimensions of the probe arrays and the chambers are so determined with respect to one another that, after a sandwich-like combination of the sensor chip with the upper portion, in each case, a precise fit reaction chamber results with an intake opening and an outlet opening over each probe array, and

(c) if necessary, an assembly for leak proof pressing together of the sensor chip and the upper portion.

A list of reference numerals is found in the brief description of the drawings of a preferred embodiment of the invention.

The advantage of the device according to the present invention with respect to the state-of-state is that an easily assemblable and disassemblable flow-through chamber for sensor chips, for example a glass sample carrier base with a probe array pressed thereon, can easily be manufactured. Furthermore, a plurality of like flow-through chambers can be positioned on such a sensor chip, so that plurality of probes can be utilized on a single sensor chip. In addition, these flow-through reaction chambers can be manually and automatically (for example with a pipette robot) filled and emptied without pressure or the production of air bubbles, so that, for example, in the case of a nucleic acid probe array, one can automatically hybridise, wash and stain.

Additional advantageous and/or preferred embodiments of the present invention are subject of the dependent claims.

The material used for the sensor chip does not have any particular limitations. In the case of the simplest case of a carrier for the sensor chip as such, a material is naturally used in which the probes in question for the probe array can be either directly or indirectly (for example, with bi-functional linkers) immobilized in a particular pattern. Naturally, one can also use correspondingly layered carriers.

According to one embodiment of the device according to the present invention, there is provided a sensor chip which has a surface made of glass, quartz, metal, metal oxide or metalloid oxides. A suitable glass surface is, for example, a simple commercially-available glass sample carrier. A suitable metal surface is, for example, aluminium. In the case of metal oxides or metalloid oxides, one can, for example, consider aluminium oxide or silicon oxide.

Typically, in the manufacture of sensor chips, these surfaces are immersed in a solution of bi-functional molecules, for example, cross-linkers (also known as linkers), which have for example halosilane (for example chlorosilane) or alkoxysilane groups for coupling on the carrier surface, so that a self-organized monolayer (SAM) is formed. In this case, the layer has a thickness of only a few Angstrom. The coupling of the linker to the sample or probe molecules results by means of a suitable additional functional group, for example, an amino or epoxy-group. Suitable bi-functional linkers for the coupling of a plurality of sample or probe molecules, particularly of biological origin, to a plurality of carrier surfaces, are known to one of ordinary skill in the art, see, for example, “Bioconjucate Techniques”, G. T. Hermanson, Academic Press, 1996.

The probes can be put onto the carrier in the form of a pattern by any suitable technique. Preferably, one works with the “Top Spot” printing technology. A general overview is, for example, found in Woelfl, Laborwelt 3, 2000, page 12 ff.

Even the material used for the upper portion is not particularly limited. For practical reasons, a synthetic material or a silicon rubber is used in one embodiment of the device according to the present invention. Examples of suitable synthetic materials are, for example, materials based on cycloolephin-copolymers (COCs), poly(methylmethacrylate) (PMMA, i.e., Plexiglas), polystyrene, polyethylene, or polypropylene. Suitable COCs are, for example, obtainable from the company Ticona, a subsidiary of Celanese AG of Kronberg/Taunus, Germany under the trade name “TOPAZ”.

Preferably, because of the possibility of directly observing assay reactions, the synthetic material is light transparent in one embodiment of the device according to the present invention. The device is, for example, transparent in the visible region of the spectrum, or, if necessary, also in the UV region.

The chambers can be worked into the upper portion in any suitable manner, and basically have any suitable shape and suitable dimensions. The only limitation resides in that, after sandwich-like combination of the upper portion with the sensor chip, precisely fit reaction chambers must be formed over the probe arrays. For example, the chambers can be drilled or milled into a plate of suitable material. Preferably, however, a pourable or sprayable synthetic material or silicon rubber is used and the upper portion is provided with chambers by means of a corresponding molding followed by subsequent, suitable mold hardening, such as by action of heat or radiation with UV light.

The intake opening and the outlet opening can be provided in the chambers of the upper portion in any suitable manner and may basically have any suitable shape or dimensions. For example, the openings can be drilled or formed by corresponding assemblies during pouring or spraying. The production of corresponding molds or the selection of suitable spray devices is known to one of ordinary skill in the art. Naturally, the intake openings and the outlet openings can basically find themselves in any suitable position of the chamber and can, for example, extend from the top, or from the side. Preferably, the intake openings and outlet openings extend through the floor of chambers in the upper portion (after sandwich-like combination of the upper portion with the sensor chip, the floors of the chambers form the ceilings of the thus formed flow-through reaction chamber), and their respective openings are opposed to one another in pairs. In this manner, a particularly flat and small volume version of the chamber is possible. Optionally, the intake openings and outlet openings can be provided as pipe ends (not shown in the drawings), over which hoses can pulled.

In a further embodiment, the intake and outlet openings can be provided with collars (not shown in the drawings) and are provided with a diameter such that a pipette tip (for example, from a hand pipette or a pipette robot) would seal the opening if placed thereon. In a particularly preferred embodiment of the present invention, the device is provided with intake openings and outlet openings in the floor of chambers, wherein the openings are round and lie opposite one another in pairs, and the chambers have a rectangular shape in the plan view. The longer side of the rectangle narrows toward its narrow side and proceeds tangentially into the respective intake opening and outlet opening (see FIG. 2). A more detailed description is found below.

It is also noted that the intake openings and the outlet openings can basically also be arranged in suitable positions outside of the probe array in the sensor chip. With the use of commercially available sensor chips, this is, however, not very practical, because corresponding drill holes must be made through the sensor chip material, which, for example, in the case of glass sample carriers, is quite laborious and brings with it the danger of breakage. For assembly and brining into service of the device according to the present invention, the upper portion and the sensor chip are combined in a sandwich-like manner, so that the chambers each form, in a precise fit, a reaction chamber over each probe array. It is therefore clear that the upper portion and the sensor chip cannot be brought into contact with another in the region of the probe array. For sealing the contact between upper portion and sensor chip a sealing material is used such as, for example, a desiccator grease or silicon rubber. It is also possible to utilize a precisely fit layer of PARAFILM®, in which corresponding number, position, shape and dimension of the probe array is cut out or punched out in corresponding regions so that the probe array is free. Supplemental sealing is, as a rule, not necessary with the use of the preferred embodiment shown in the figure having a silicon rubber mat with chambers and intake/outlet openings in the floor.

If necessary or desirable, the upper portion 15 and the sensor chip 5 can be pressed on each other with a suitable assembly, in order to strengthen the sealing effect. Suitable in this regard, are appropriately dimensioned clips, which can be put onto the rim, or the combination of upper portion and sensor chip is positioned between press plates, which can be pressed together. This embodiment has the advantage that the applied pressure is evenly distributed. In the latter case, one must naturally secure the respective intake and outlet openings in the press plate such that the intake and outlet openings are accessible in the chambers of the upper portion. A particularly advantageous embodiment is shown in the figures and will be further described in the detailed description of preferred embodiments, which follows. As a matter of principle, the upper portion and the sensor chip can also be permanently bound to one another, for example, by chemical binding, for example with an adhesive, through ultrasound or laser welding of synthetic materials. In this case, the upper portion is, for example, light transparent in order to be suitable for reading of the sensor chip.

The device according to the present invention is used so that the sample is introduced into a flow-through reaction chamber with a corresponding probe array through the inlet opening (or outlet opening, according to the purpose of the use) by, for example, manual pipetting, pipetting with a pipette robot or with a controlled volume pump. After incubation to bind the sample components to specific probes—for example, binding a target nucleic acid with a particularly sought-after sequence to its complementary probe nucleic acid sequence through hybridisation—one can proceed with, for example, washing, drying and detection steps without having to open the reaction chamber.

The detection reagents used are not particularly limited, and can, according to the mission or purpose of the device, be selected from one or more of unmarked or marked polyclonal or monoclonal antibodies, chimeric antibodies or “single chain” antibodies or functional fragments or derivatives thereof. Functional, in this context, means that the antigen binding ability of the particular fragment or derivative is conserved, without the fragment or derivative also having an immunological effect.

The respective marking can be done in any suitable manner, and, for example, can be selected from radioactive marking, coloring, fluorescence, bioluminescence, chemoluminescence or phosphorescence marking or can be based on the function of an enzyme, an antibody or a functional fragment or derivative thereof or from a protein A/gold, protein G/gold, or avidin/strepdavidin/biotin system.

It is clear that the actual detection reaction can take place directly or indirectly. In the case of, for example, an antibody as a detection reagent, direct detection could depend on the binding of a specific, marked antibody. An indirect detection could rely on the binding of an unmarked primary antibody on an antigen (for example, a protein in the sample), which then subsequently binds a marked secondary antibody against the primary antibody (so-called anti-antibodies) (a so-called sandwich assay method).

In order to seal the inlet and outlet openings, for longer reaction times, a cover strip can be used. One must take care however that during injection in the inlet and outlet openings no overpressure is built up in the reaction chambers, which could lead to leaks. Alternatively, in order to provide evaporation protection for the media in the reaction chambers during long reaction times, a surface seal can be provided that does not change the volume of the chambers.

In a still further embodiment, the upper portion, which is provided with chambers, can form the replaceable bottom portion of a plunger provided with connections for various media (not shown in the drawings). In this way, sensor chips with probe arrays can be positioned, one after the other, under this plunger by means of a suitable transport system (for example, with integrated, programmable heating, not shown in the figures). In this manner, the plunger is pressed onto the sensor chip in question over the z-axis, wherein, by means of media connections, the samples and all necessary reagents (for example, rinse and drying media, and colorants) are pumped and/or aspirated through the reaction chambers. The plunger is then picked up, and, lastly, the upper portion is automatically disposed of and a new one for the next sensorship is fastened to the plunger.

As follows, the invention will be described without limitation by means of the illustrative embodiments pictured in the figures. Further objects, features and advantages will become apparent from the Detailed Description of the Preferred Embodiments, which follows, when considered together with the attached figures.

### BRIEF DESCRIPTION OF THE DRAWINGS

FIG. 1 shows a sensor chip (also called a chip in the following) 5 with a probe array 10 in the form of an arrangement of drops on a glass sample carrier in plan view.

FIG. 2a shows a silicone mat 40 with preformed chambers 20 and inlet and outlet openings 25, 30 in plan view (as seen from below). FIG. 2b shows the dimensions of a single chamber 20.

FIG. 3a shows a silicone mat 40 in plan view (as seen from above). FIGS. 3b and 3c are perspective views showing silicone mat 40 from above and below, respectively. FIGS. 3d and 3e are cross sectional views through sections A-A and B-B, respectively in FIG. 3a.

FIG. 4a shows top plan view of a press plate 80 with bore holes 100. FIG. 4b shows press plate 80 in side view, from the bottom of FIG. 4a.

FIG. 5a shows a top plan view of pusher 90 with pusher noses 65. FIG. 5b is a side view of pusher 90 from the bottom in FIG. 5a.

FIG. 6a shows a chip holder 95 with stop 50, clearance 70 and push groove 75 in top plan view. FIG. 6b shows a cross section of chip holder 95 along line B-B in FIG. 6a. FIG. 6c shows a cross section along line A-A in FIG. 6A. FIG. 6d shows a top perspective view of chip holder 95.

FIG. 7a shows an assembled device according to the present invention, including a chip holder 95 with chip 10, silicone mat 40 with chambers and inlet and outlet openings 25, 30, press plate 80, pusher 90 and cover strip 85. FIG. 7b shows a cross section along line B-B in FIG. 7a. FIG. 7c shows a cross section along line C-C in FIG. 7a, and FIG. 7d shows a cross-section along line A-A in FIG. 7a.

FIGS. 8a and 8b show cover strip 85 in top and side views, respectively.

Reference Numeral List

| | |
|---|---|
| 5 | sensor chip |
| 10 | probe array |
| 15 | upper portion |
| 20 | chambers |
| 25 | inlet opening |
| 30 | outlet opening |
| 40 | silicon mat |
| 50 | stop |
| 55 | side frame |
| 60 | knob |
| 65 | push nose |
| 70 | push nose clearance |
| 75 | pusher groove |
| 80 | press plate |
| 85 | cover strip |
| 90 | pusher |
| 95 | chip holder |
| 100 | bore hole |

### DETAILED DESCRIPTION OF THE PREFERRED EMBODIMENTS

The present invention will now be discussed with respect to certain illustrative preferred embodiments shown in the figures in which like parts are referred to by like reference numerals.

The embodiment of the device according to the present invention shown in the figures is put into practice as follows.

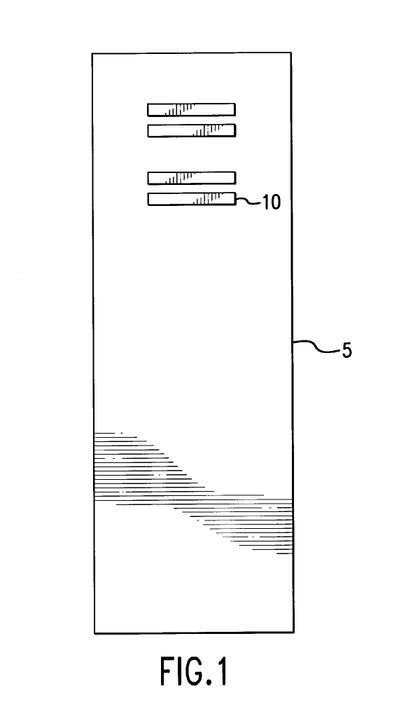

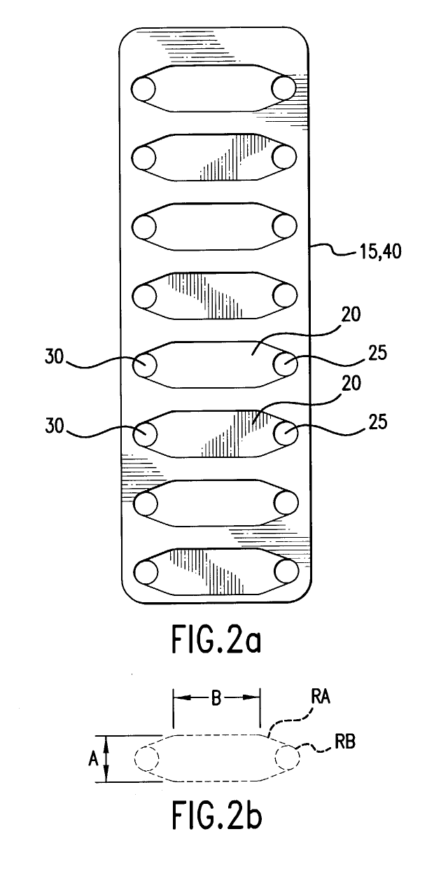

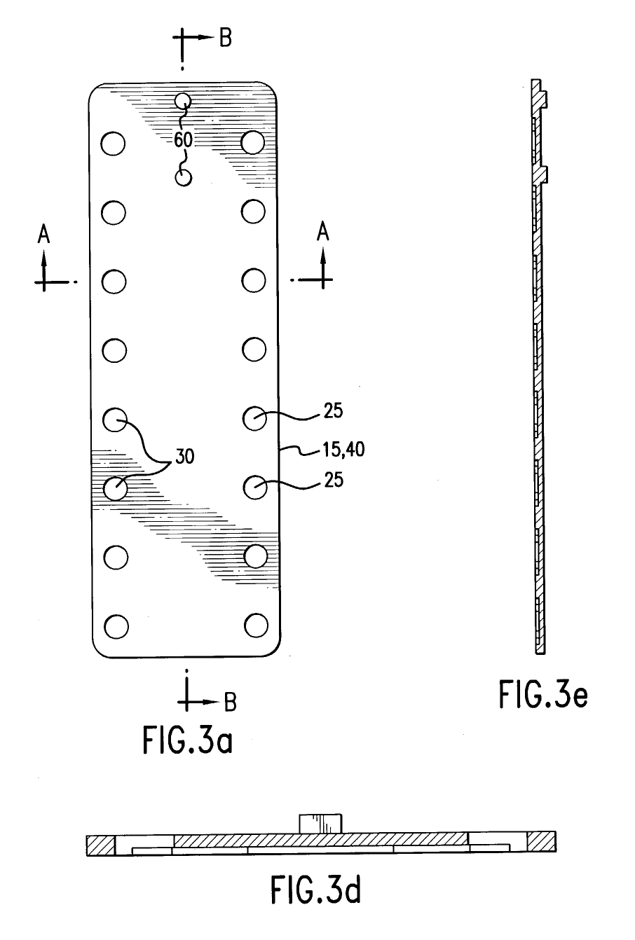

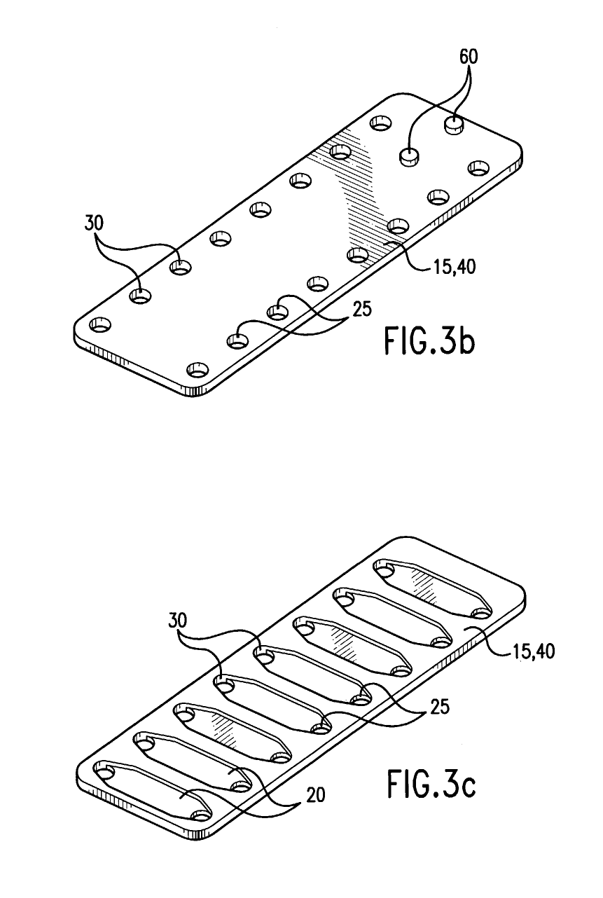

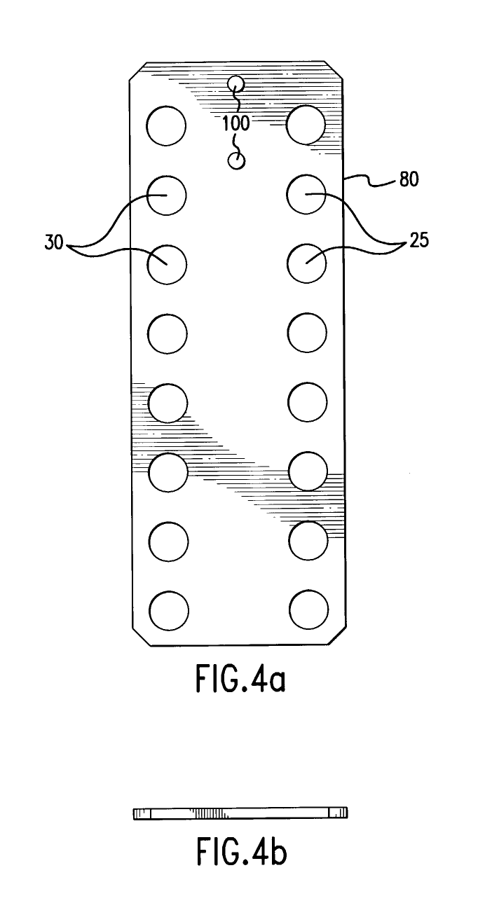

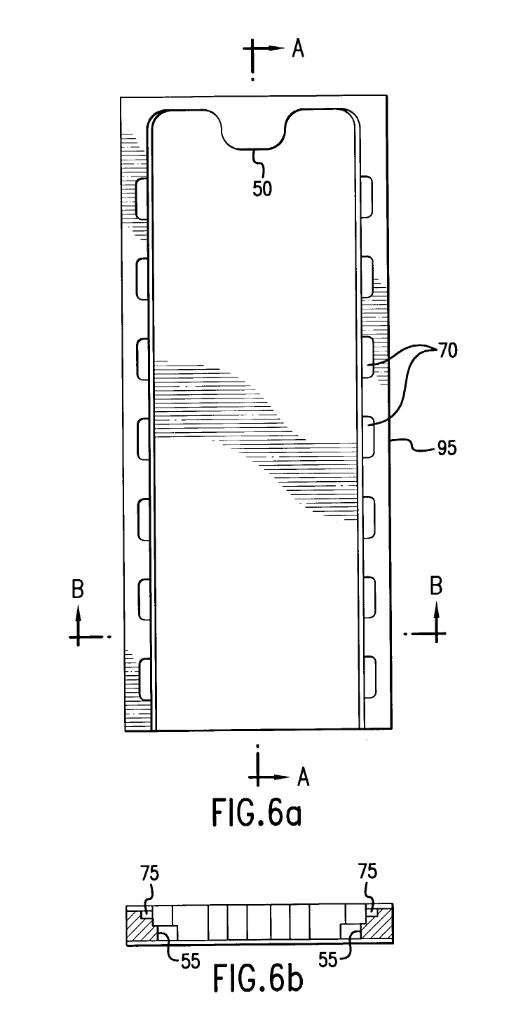

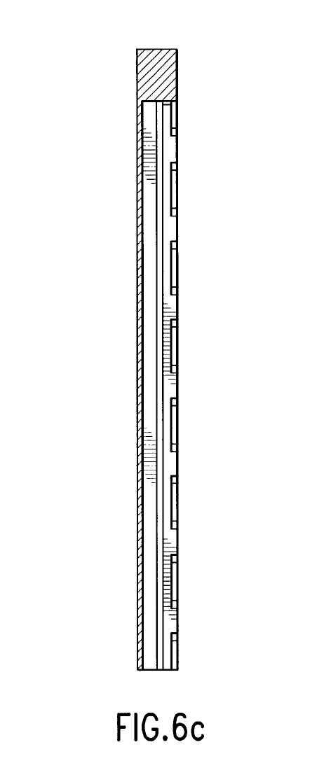

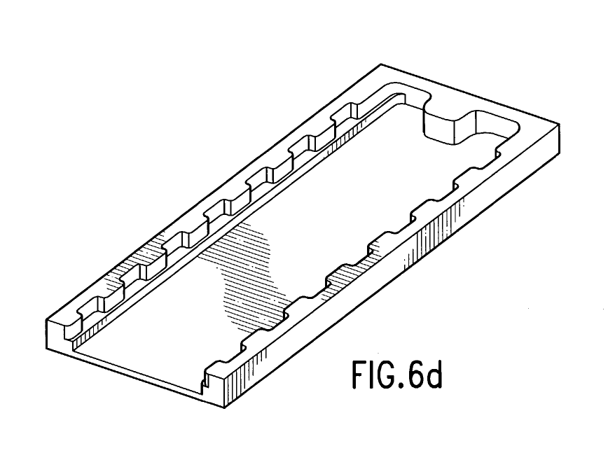

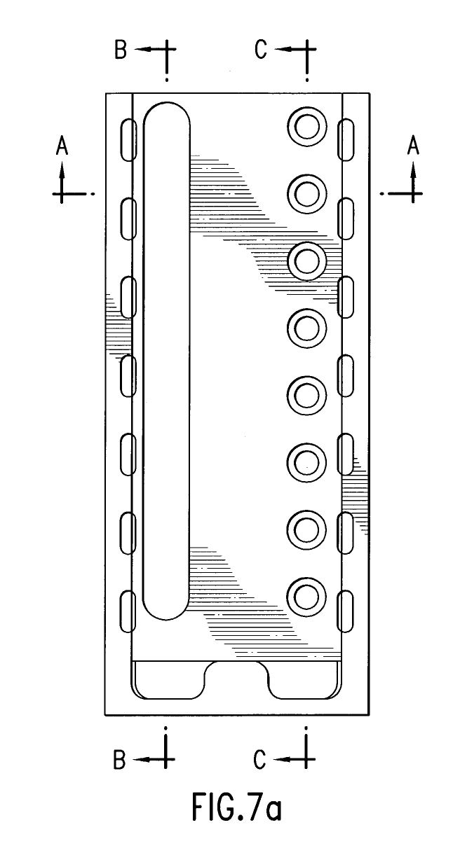

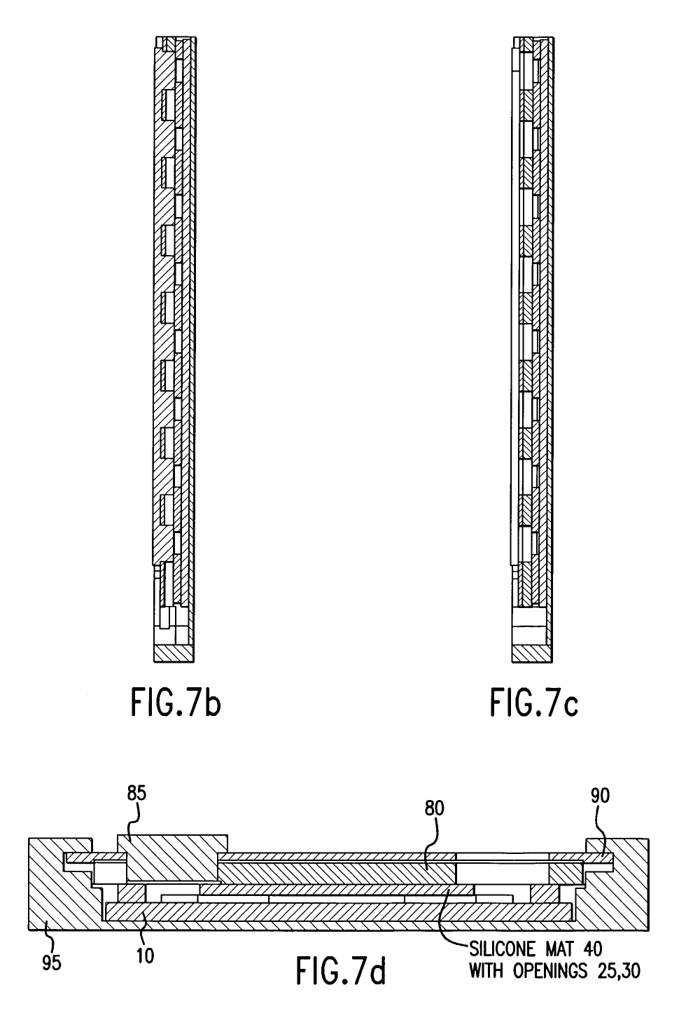

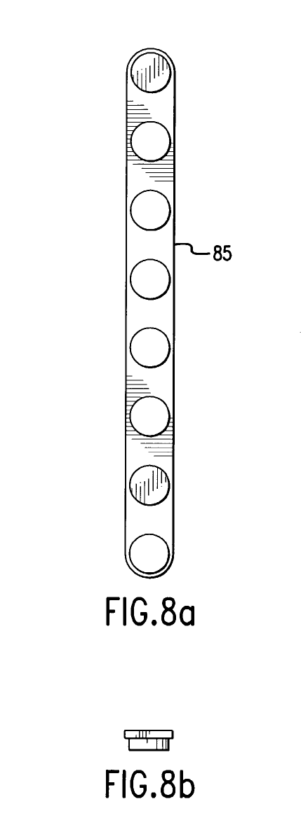

A chip 5, which is provided with a probe array 10 in the form of a arrangement of drops on the chip 5 (for example, a glass sample carrier, that is, for example printed with the “Top Spot” printing technique, see Woelfl, supra) (FIG. 1), is placed in a chip holder 95 (FIG. 6, FIG. 7). The position of the chip 5 is thereby defined by the stop 50 and the side frame 55. The silicone rubber mat 40 (FIG. 2) with chambers 20 and inlet and outlet openings 25, 30 is then placed on the press plate 80 (FIG. 3, FIG. 4). The relative position of both parts is fixed by means of two knobs 60 in the silicone mat 40, which are pressed in bore holes 100 (having, for example, a diameter of two millimetre) provided in the press plate 80. The silicone mat 40 sticks to the smooth surface of the press plate 80 by adhesion, because of which the actually bendable and slack silicon mat 40 is very easily manipulable.

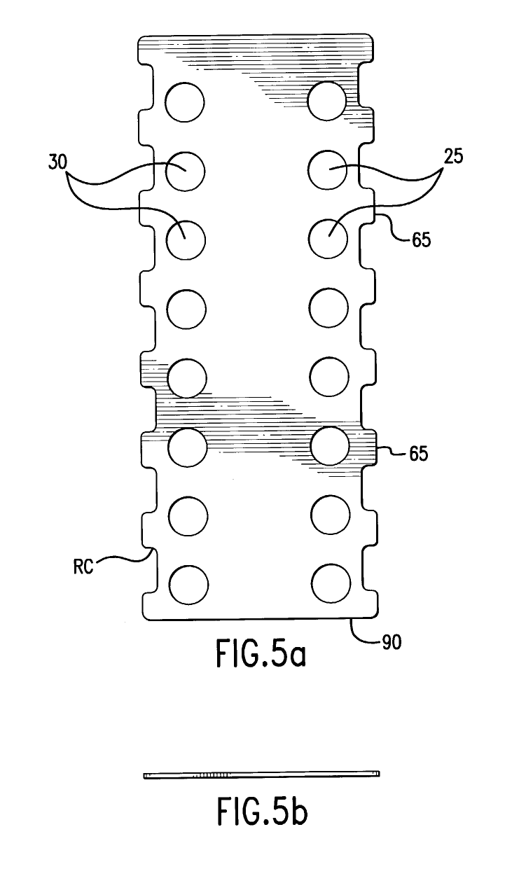

The press plate 80 with its fastened silicone mat 40 with chambers 20 and inlet and outlet openings 25, 30 is laid in the chip holder 95 on the chip 5. In this way the stop 50 and side frame 55 serve for positioning. In order to provide the required pressure to seal the individual reaction chambers on the chip 5 a pusher 90 (FIG. 5) is secured onto the chip holder 95. For this purpose, the pusher 90 with its pusher noses 65 is placed in the corresponding clearances 70 in the chip holder 95. The pusher 90 is thereafter pressed onto the underlying parts (chip 5, silicon mat 40, and press plate 80), until it moves forward in the pusher groove 75 up until stop 50. The press plate 80 distributes the pressure on the tensioned pusher 90 and chip holder 95 over the entire surface of silicone mat 40. It is clear that the pusher 90 comprises corresponding inlet and outlet openings 25, 30, so that the inlet and outlet openings 25, 30 in the chamber 20 of the upper portion remain accessible.

At this point, the reaction chambers can be filled by means of inlet openings 25. The filling can take place, for example, by means of hand pipettes, or with a pipette robot. By means of the geometry of the reaction chamber (i.e., radii and chamber height) the reaction chambers can be completely filled without air bubbles with a pressureless dosaging of about 40 microliters of sample or reagent. In order to prevent entrapment of the air, it is important that one always fills through one of the openings, the inlet opening 25, and that the other of the openings, outlet opening 30, is used to de-air or aspirate. It is clear that the inlet opening 25 can also serve as outlet opening 30, and vice versa.

The distance of the inlet openings to one another preferably comprises a multiple of 9 mm, because this is the normal distance in titration plates, multiple pipettes and pipette robots.

After the samples have reacted with the probes in the probe array 10 on the chip 5 (various protocols with different length reaction times and temperatures are possible, for example determined by a regulated and programmed heating plate), the reaction chambers must be rinsed. For this purpose, wash medium is pumped into the inlet opening and aspirated from the outlet opening. Before disassembly of the device, the reaction chambers are dried (for example, by blowing through nitrogen). For disassembly, one carries out the assembly steps in the reverse order.

Silicone mat 40 with chambers 20 can be, in this embodiment, poured from two-component silicon rubber ELASTOSIL® RT 601A/B, available from Wacker-Chemie GmbH of Munich, Germany. In order to obtain freedom from air bubbles in the thin material, the silicone mats 40 are preferably poured in a metal mold and hardened in a vacuum oven.

In further versions of the above-described embodiments, the inlet and outlet openings 25, 30 can be provided with a collar fit in diameter so that a pipette tip, for example, from a hand pipette or a pipette robot, would seal the opening when placed on the collar.

A cover strip 85 can be used to seal the inlet and outlet openings 25, 30, for example, with longer reaction times. It is nonetheless necessary to take note that during injection in the inlet and outlet openings 25, 30, no overpressure is created in the reaction chambers that could lead to leaks. Alternatively, a flat seal that does not change the volume of the chambers can be provided in order to provide protection from evaporation.

In a further version of the above-described embodiment, the silicone mat 40 forms a plunger (or stamp) with connections for media for the chambers of the exchangeable sensor chip. In this manner, the probe arrays 10 of the printed chips 5 can be positioned under this plunger by a suitable transport system (for example, with integrated, programmable heating). The plunger is pressed onto the chip 5 over a z-axis. Through the media connections, all necessary reagents (sample, rinse and drying media) are pumped and/or aspirated through the reaction chambers. Thereafter, the plunger is taken off and subsequently, a silicon mat is automatically disposed of and a new one fastened to the plunger.

While the present invention has been described with reference to certain preferred embodiments, one of ordinary skill in the art will recognize that additions, deletions, substitutions, modifications and improvements can be made while remaining within the spirit and scope of the present invention as defined by the appended claims.

What is claimed is:

1. A device with one or more flow through reaction chambers for investigation of one or more samples on a sensor chip, comprising:
(a) a sensor chip;
(b) a number of probe arrays corresponding to a number of samples to be investigated, arranged on the sensor chip spatially separated from one another;
(c) an upper portion; and
(d) a number of spatially separated chambers disposed in the upper portion corresponding in number to the number of probe arrays, the chambers being each provided with an inlet opening and an outlet opening, wherein the position and dimension of the probe arrays and the chambers is relatively determined so that, after a sandwich-like combination of the sensor chip with the upper portion a respective precise fit reaction chamber is formed over each probe array with an inlet opening and an outlet opening.

2. A device according to claim one, further comprising:
an assembly arranged to press together the sensor chip and the upper portion.

3. A device according to claim 1, wherein the sensor chip comprises a surface selected from the group consisting of glass, metal, metal oxide and metalloid oxide.

4. A device according to claim 1, wherein the sensor chip comprises a surface comprising glass.

5. A device according to claim 1, wherein the sensor chip comprises a surface comprising metal.

6. A device according to claim 1, wherein the sensor chip comprises a surface comprising metal oxide.

7. A device according to claim 1, wherein the sensor chip comprises a surface comprising metalloid oxide.

8. A device according any one of claims 1-7, wherein the upper portion is made of a synthetic material.

9. A device according any one of claims 1-7, wherein the upper portion is made of silicone rubber.

10. A device according to claim 3, wherein the synthetic material is light transparent.

11. A device according to claim 1, wherein the inlet opening and the outlet opening extend through the floor of each chamber.

12. A device according to claim 5, wherein the chambers have the shape of a rectangle in top view, and narrow themselves in the direction of the narrow side and tangentially lead to the inlet openings and the outlet opening.

13. A device according to claim 1, further comprising a chip holder dimensioned to securely hold the chip, wherein the upper portion comprises a silicone rubber mat in which said chambers with inlet openings and outlet openings are formed, and a press plate disposed above the silicon mat, and a pusher disposed above the press plate.

14. A device according to claim 13, wherein the chip holder comprises a pusher groove dimensioned to movably receive the pusher, wherein the pusher comprises a plurality of pusher noses, and wherein the chip holder further comprises a plurality of pusher clearances corresponding in number to the number of pusher noses, wherein the pusher is insertable into the pusher grooves by inserting the pusher noses into the pusher clearances so that the pusher is slidable in the pusher groove, and, wherein, when the pusher is slid so that the pusher noses are displaced from the pusher clearances, the chip holder, chip, silicon mat, and press plate are securely held together and the precise fit reaction chambers are formed.

15. A device according to claim 14, further comprising a sealing strip dimensioned to seal the outlet openings.

16. A device according to claim 14, further comprising a sealing strip dimensioned to seal the inlet openings.

17. A device according to claim 15, further comprising a second sealing strip dimensioned to seal the inlet openings.

18. A device according to claim 14, wherein one of the silicone mat and the press plate is provided with one or more knobs dimensioned to fit in one or more bore holes provided in the other of the silicone mat and the press plate.
